(19) United States
(12) Patent Application Publication
(10) Pub. No.: US 2017/0294601 A1
(43) Pub. Date: Oct. 12, 2017

(54) Iridium complex, method for manufacturing same, and organic light-emitting devices using same

(71) Applicant: AAC Technologies Pte, Ltd., Singapore City (SG)

(72) Inventors: Youxuan Zheng, Nanjing (CN); Yi Pan, Nanjing (CN); Yi Wang, Nanjing (CN); Jinglin Zuo, Nanjing (CN); Qiulei Xu, Nanjing (CN)

(21) Appl. No.: 15/480,500

(22) Filed: Apr. 6, 2017

(30) Foreign Application Priority Data
Apr. 7, 2016 (CN) 201610211554.5

(51) Int. Cl. H01L 51/00; C09K 11/06; C07F 15/00

(52) U.S. Cl. CPC H01L 51/0085; H01L 51/0025; C07F 15/0033; C09K 11/06; H01L 51/5016

(57) ABSTRACT

An iridium complex is disclosed. The iridium complex with tetra(4-fluorophenyl) phosphorane as an auxiliary ligand, the series of iridium complex takes any one of 2-(4,6-bi trifluoromethyl)pyridine, 2-(4,6-bi trifluoromethyl)pyrimidine, 2-(4,6-bi trifluoromethyl)pyrazinyl and 2-(4,6-bi trifluoromethyl) triazine derivatives as primary ligands in its molecule. The new type of iridium complex covered by the present invention has not only such advantages as high luminous efficiency, high electron mobility, stable chemical property, easy for distillation and purification but also good performance of devices. By modifying the molecular structure of the primary ligands, it allows to adjust the luminous intensity and efficiency of the complex, thus facilitating the design and production of organic light-emitting diode and illumination source.

### FIELD OF THE PRESENT DISCLOSURE

The present invention relates to novel organic compounds that may be advantageously used in organic light emitting devices. More particularly, the invention relates to iridium complexes and their use in OLEDs.

### DESCRIPTION OF RELATED ART

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE, coordinates, which are well known to the art.

In recent years, many researches indicate that the iridium complex is regarded as the most ideal selection of OLEDs phosphor materials among many heavy metal element complexes. After forming +3 cation, the Iridium atoms with 5d⁷6S² outer electron structure owns the 5d⁶ electron configuration and the stable hexa-coordinate octahedral structure, which lets the materials own higher chemical stability and heat stability. Meanwhile, Ir(III) owns larger spin-orbit coupling constants (ξ=3909 cm-1), which is conductive to improving the quantum yield of complexes and reducing the luminescence Lifetime, thus improving the whole performance of illuminator.

As the phosphor materials, in general, the iridium complex easily causes in the microsecond phosphorescence quenching between triplet-triplet of iridium complex and triplet-polaron. In addition, in the current common materials, the hole mobility of hole-transport material is far higher than the electronic mobility of electron transport material, and the common host materials give priority to the hole transport, which would cause that many redundant electron holes gather on the luminescent layer and electron transfer layer surface. All these factors would result the efficiency reduction and the severe efficiency roll-off It's indicated in the research that: in case of owning higher electronic transmission ability, the iridium complex could effectively increase the transmission and distribution of electron in luminescent layer, expand the area of electron-hole and balance the quantity of electron-hole pairs, which greatly improves the efficiency of device and reduces the efficiency roll-off

Thereof, it is necessary to disclose and provide improved Iridium complex to overcome the above-mentioned disadvantages.

### BRIEF DESCRIPTION OF THE DRAWINGS

FIG. 1 is an electroluminescent spectra of an iridium complex GIr4-001 used in an organic light-emitting device;

FIG. 2 is an photoelectric property of the iridium complex GIr4-001 used in the organic light-emitting device; and

FIG. 3 is an photoelectric property that the iridium complex GIr4-001 used in the organic light-emitting device.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

All the iridium complexes of the invention have used iridium chloride hydrate, 4,6-2-(trifluoromethyl)pyridine-3-boric acid, 4,6-2-(trifluoromethyl)pyridine-4-boric acid, 2-bromopyridine derivatives, 2-bromopyrimidine derivatives, 2-bromopyrazine derivatives, 2-bromotriazine derivatives etc, in the synthesis process with the similar method of synthesis. The iridium dimer bridging ligand contains two primary ligands with a tetra(4-fluorophenyl)phosphorane auxiliary ligand, the primary ligands are any one of 2-(4,6-bi trifluoromethyl)pyridine, 2-(4,6-bi trifluoromethyl)pyrimidine, 2-(4,6-bi trifluoromethyl)pyrazinyl and 2-(4,6-bi trifluoromethyl) triazine derivatives; then add the mixed solution into 2-ethoxyethanol solution, conduct heating reaction under 120-140° C. for a reaction time of 12-48 h, cool to room temperature, eliminate the solvent through depressurization and distillation, then extract and concentrate with dichloromethane, get the crude product of the ligand through column chromatography isolation, and get pure iridium complex through sublimation. Wherein, the iridium complex contains 2-(4,6-bi trifluoromethyl) pyridine, 2-(4,6-bi trifluoromethyl)pyrimidine, 2-(4,6-bi trifluoromethyl) pyrazinyl and 2-(4,6-bi trifluoromethyl) triazine derivatives, the mole ratio of the iridium dimer bridging ligand: the tetraphenylphosphorane: sodium carbonate is 1:2:5.

In the primary ligands, the pyridine derivatives ligating with iridium by C atom are:

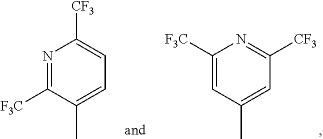

the pyridine derivatives have different positions of linking with the pyridine, pyrimidine, pyrazinyl and triazine derivatives in different primary ligands; and the arbitrary positions of the pyridine, pyrimidine, pyrazinyl and triazine derivatives are substituted by halogen or alkyl, the number of substituent groups on the pyridine are 0-4, that on the pyrimidine and pyrazinyl are 0-3, that on the triazine are 0-2. The halogen is F, the alkyl group is any one of trifluoromethyl and methyl. The 4,6-bi trifluoromethyl in different primary ligands has different positions of linking with the pyridine, pyrimidine, pyrazinyl and triazine derivatives in different primary ligands, which are taken from 3-position and 4-position; the pyridine, pyrimidine, pyrazinyl and triazine derivatives are selected from any one of

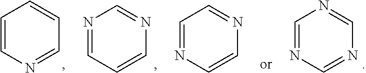

The iridium complex corresponds to different primary ligand and has the following different structures:

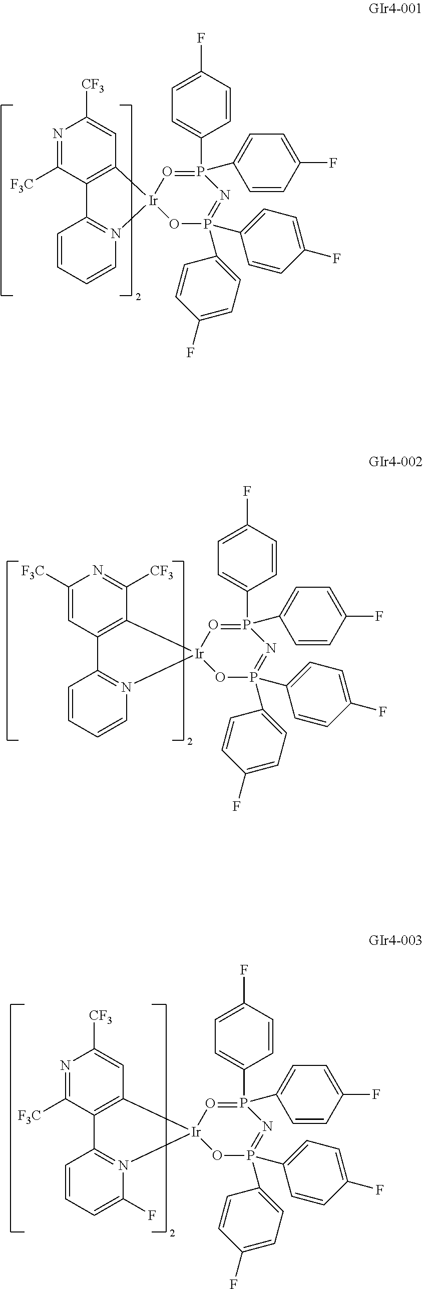

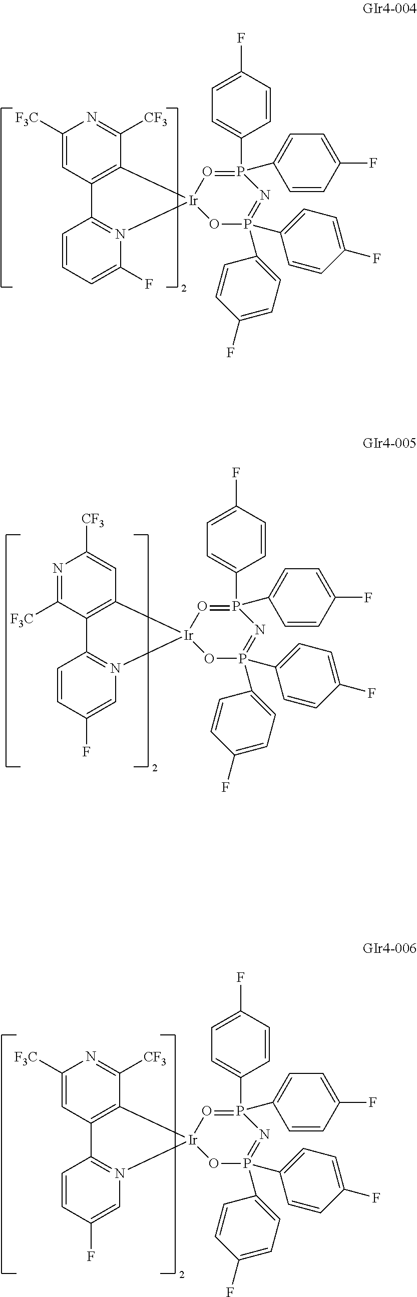

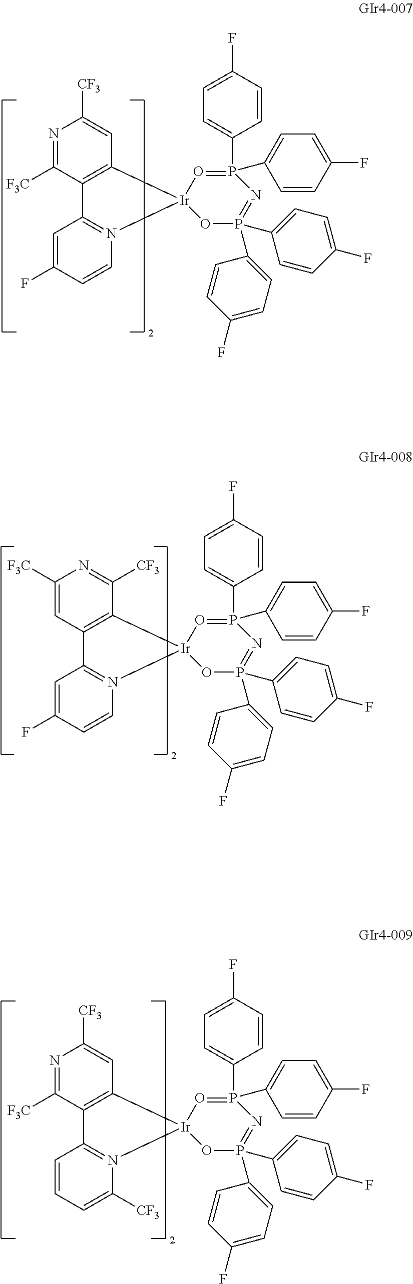

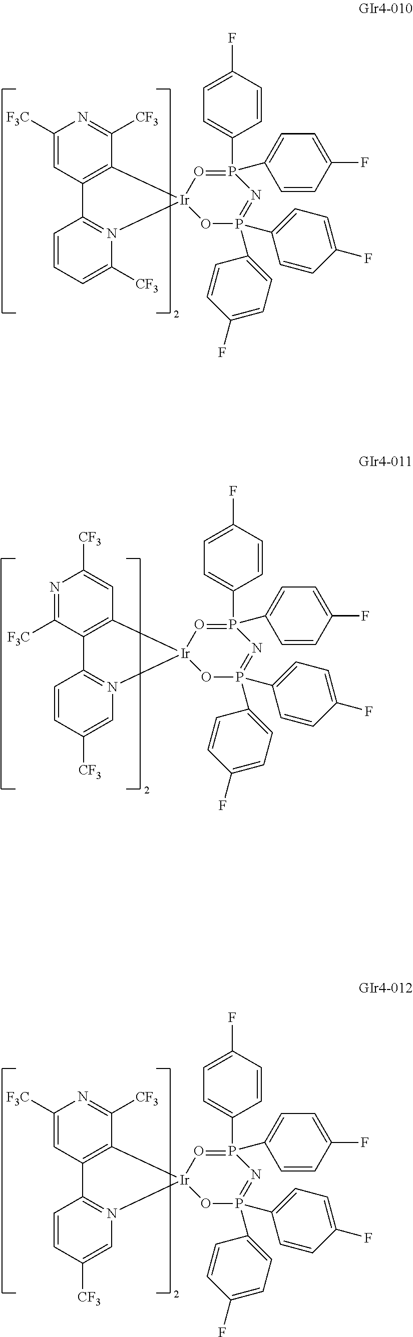

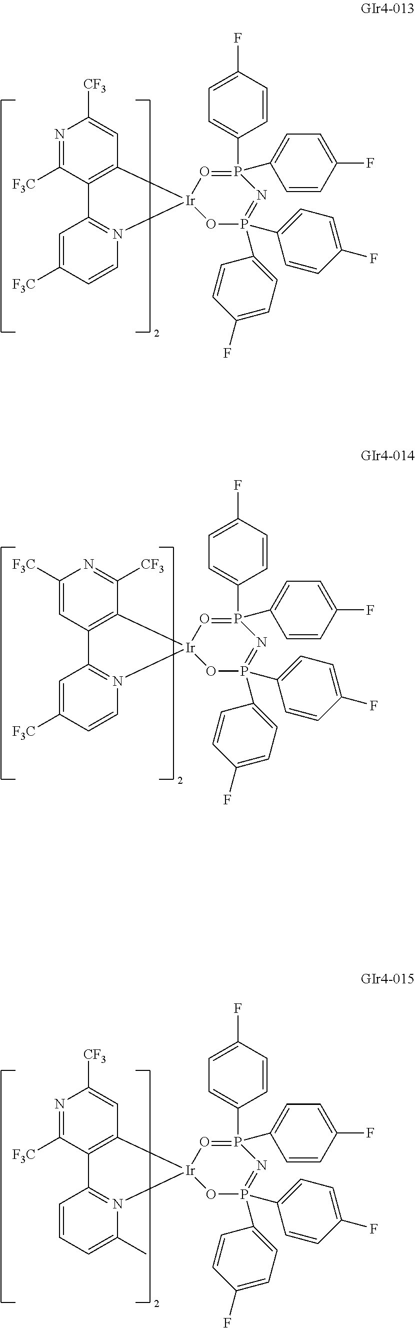

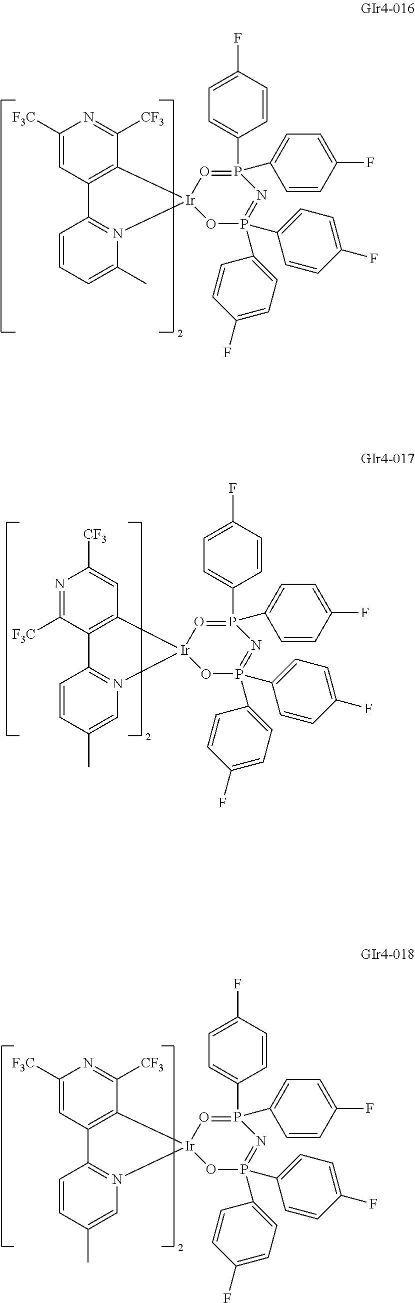

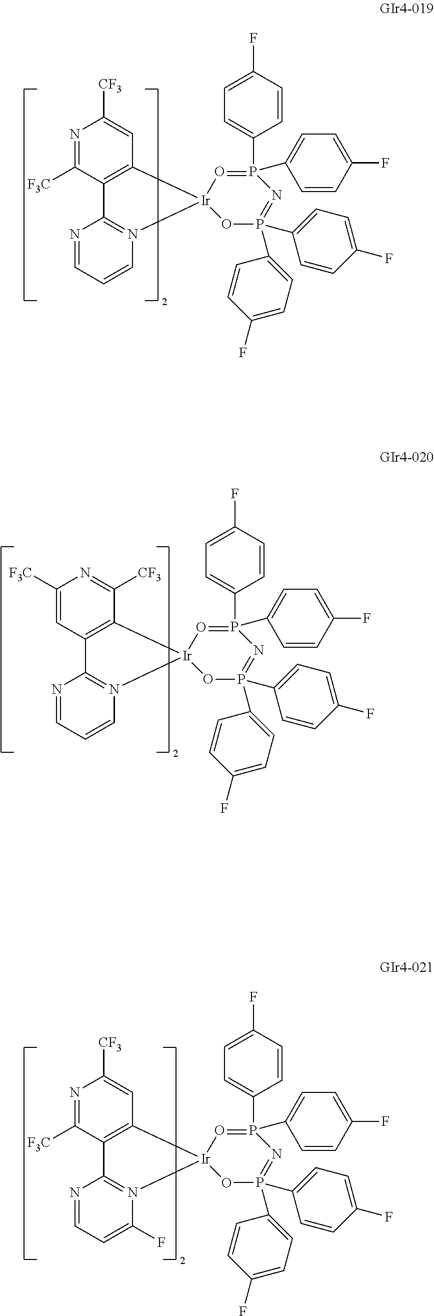

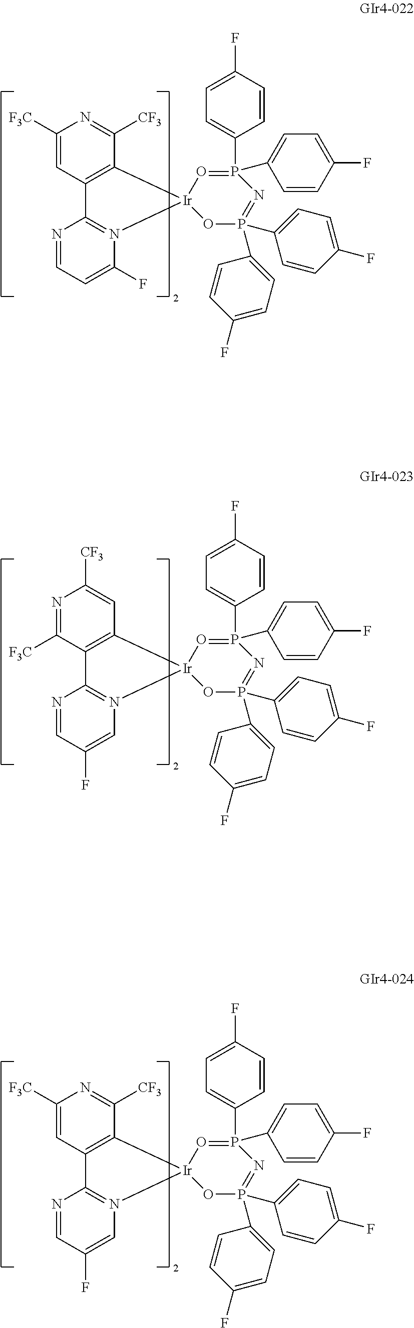

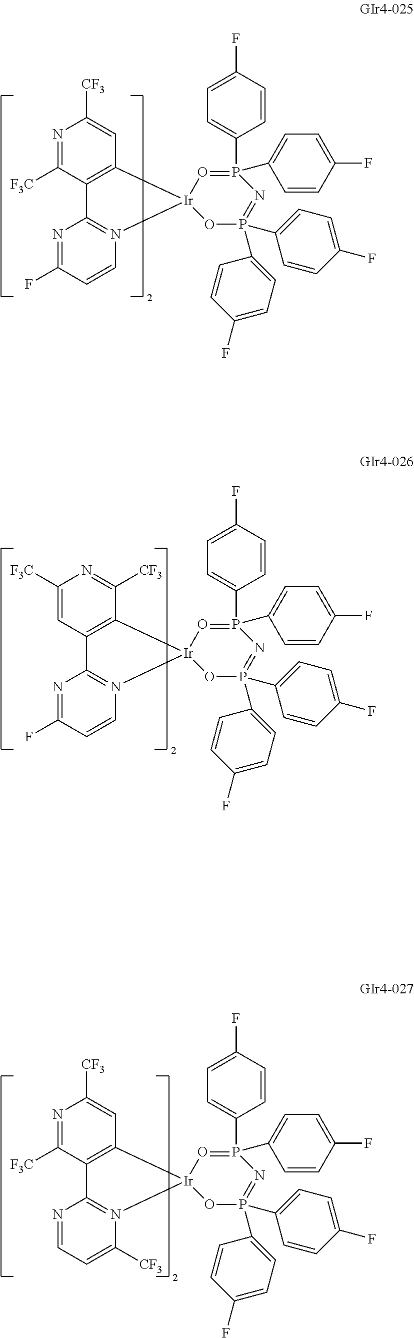

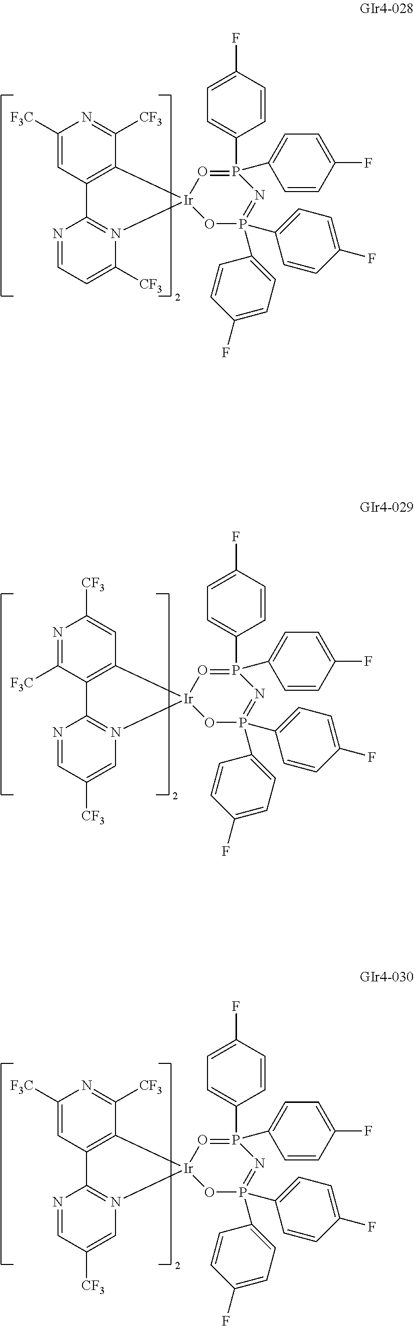

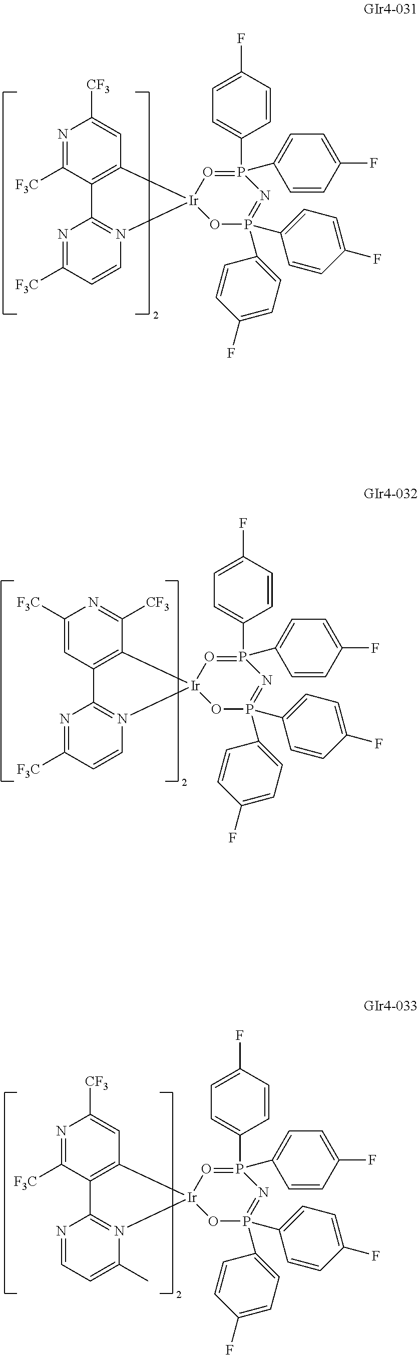

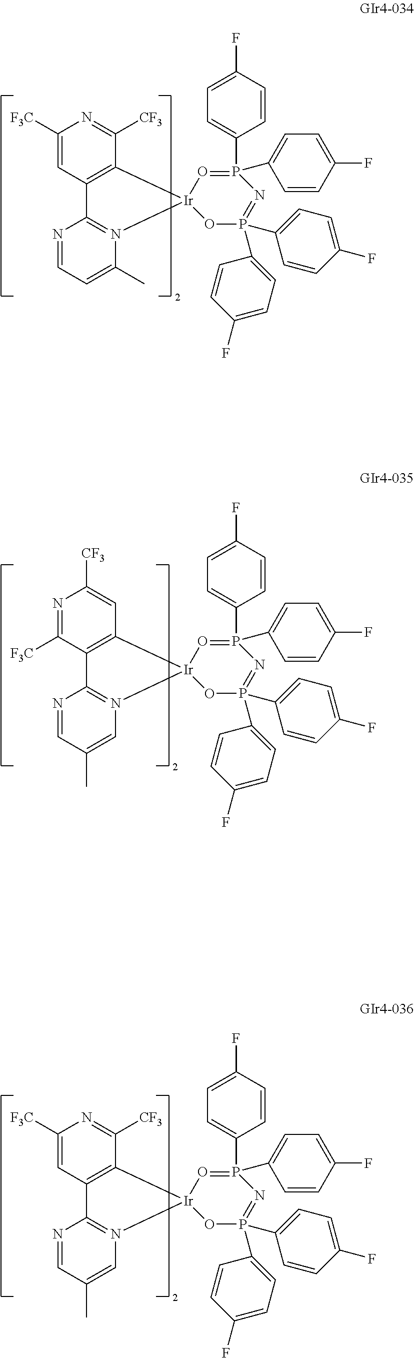

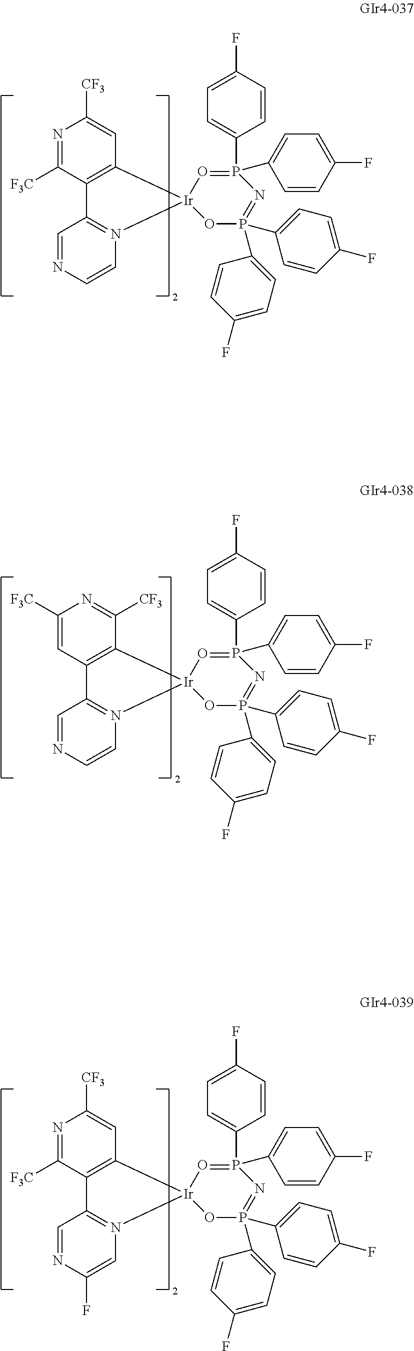

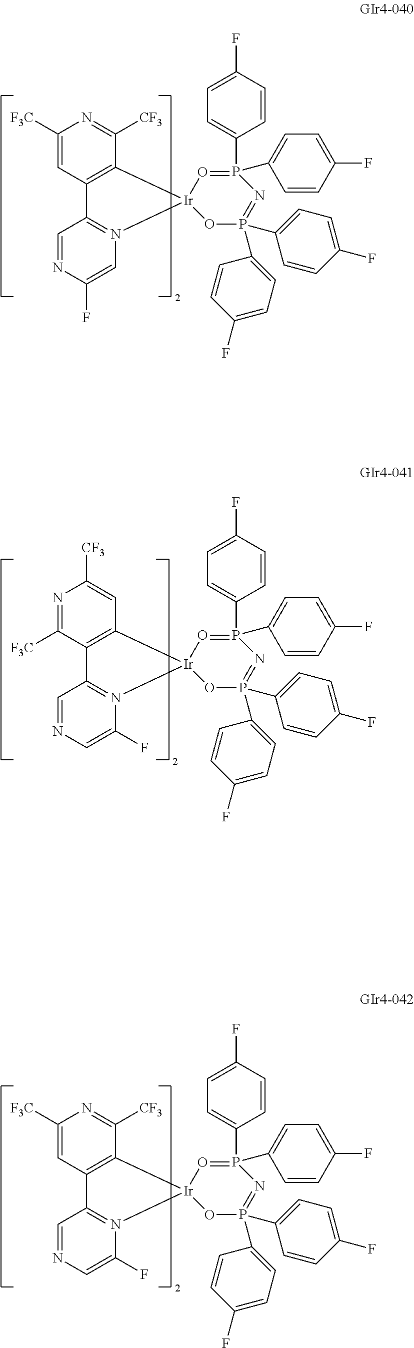

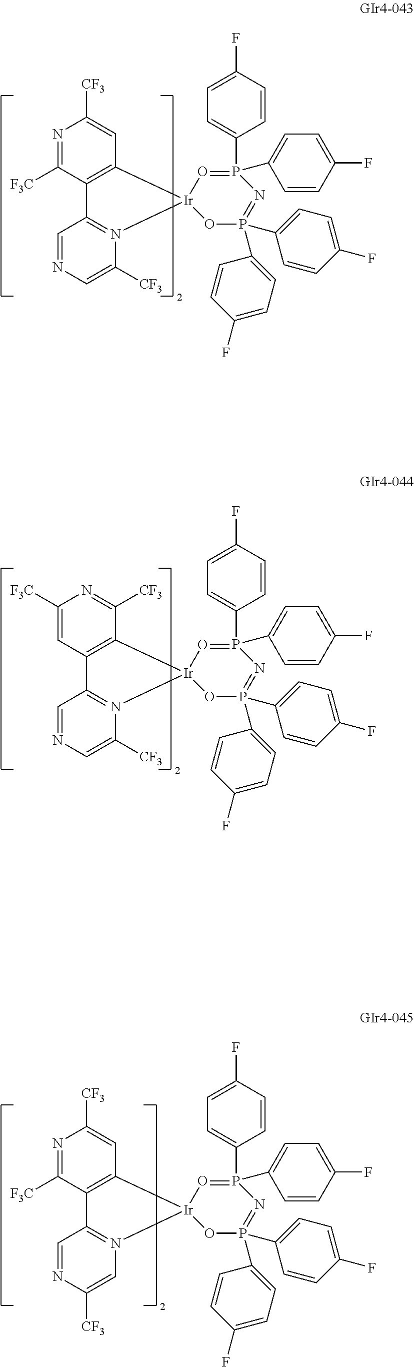

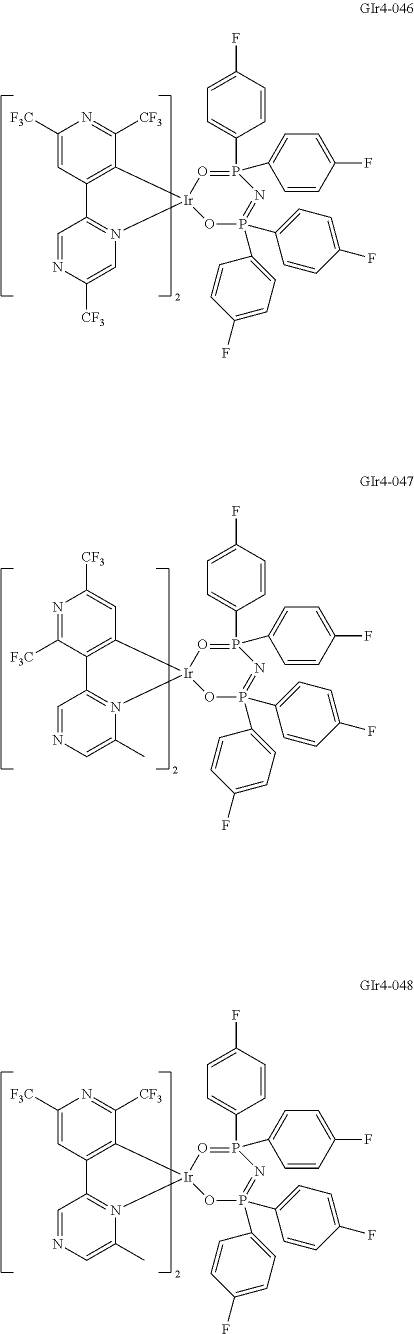

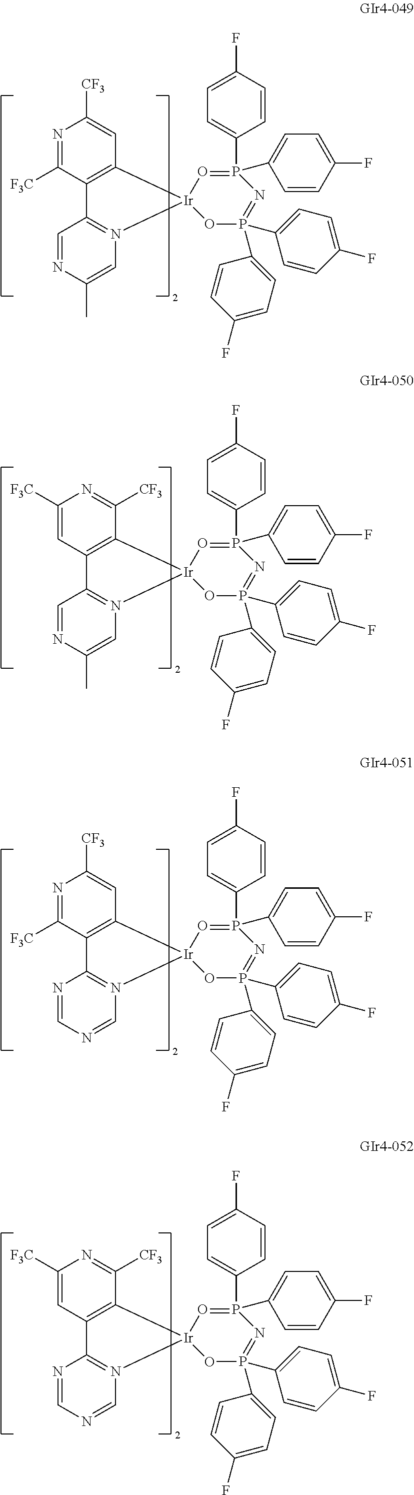

The invention is further described below with reference to one of the embodiments of complex GIr4-001, to help improve understanding of the invention, but not limit to the present invention.

Manufacturing method of complex GIr4-001

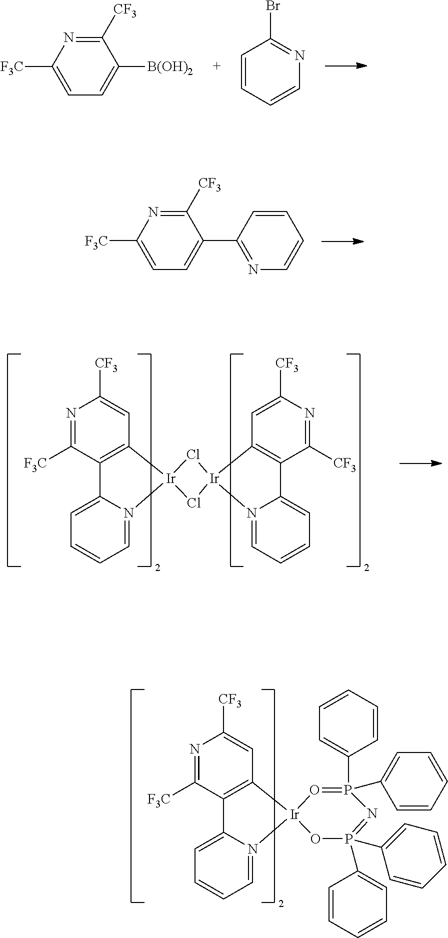

Dissolve 2-bromopyridine (26.39 mmol), 4,6-4,6-2-(trifluoromethyl) pyridine-3-boric acid (31.66 mmol), tetrakis (triphenylphosphine) palladium(0.79 mmol) and sodium carbonate (60.00 mmol) in 10 mL of tetrahydrofuran, react under 65° C. for 24 hours and cool, add water and dichloromethane, then get the primary ligand through organic layer concentration column chromatography (yield of 52.24%). Dissolve the primary ligand (13.08 mmol) and iridium chloride hydrate into 15 mL of 2-ethoxyethanol, the mixture reacts under 130° C. for 12 h, then add tetraphenylphosphorane (12.46 mmol) and sodium carbonate (60.00 mmol), then continue to react under 130° C. for 24 h. Systematic cooling, add water and dichloromethane, get yellow solid GIr4-001 through organic layer concentration column chromatography (yield of 44%).

NMR and mass spectrometry characterization:1H NMR (500 MHz, CDCl3) δ 9.09 (d, J=5.6 Hz, 2H), 8.29 (d, J=8.4 Hz, 2H), 7.79 (dd, J=12.4, 7.7 Hz, 4H), 7.67 (t, J=8.0 Hz, 2H), 7.39 (ddd, J=19.9, 13.9, 7.5 Hz, 10H), 7.19 (t, J=7.4 Hz, 2H), 7.01 (t, J=6.7 Hz, 4H), 6.85 (t, J=6.5 Hz, 2H), 6.36 (s, 2H). ESI-MS: m/z 1192.67 [M]+, found: m/z 1192.13[M]+.

The invention takes any one of 2-(4,6-bi trifluoromethyl)pyridine, 2-(4,6-bi trifluoromethyl)pyrimidine, 2-(4,6-bi trifluoromethyl)pyrazinyl and 2-(4,6-bi trifluoromethyl) triazine derivatives as primary ligands, with tetraphenylphosphorane as auxiliary ligand, to design and synthesize a series of green emitting iridium complexes. By design of ligand or complex structure, and by modification of simple chemical substituent on the ligand, it achieves the goal of regulating luminescence and electron mobility of the complex.

All the azacycles are groups with relatively high electron transmission performance, facilitating to balance the import and transmission of carriers.

The iridium complexes has relatively high luminous efficiency and high electron mobility, and can be prepared by simple method with high yield after optimization and verification.

Preparation of Organic Light-Emitting Diode Devices

Next the preparation of organic light-emitting diode devices of the invention is described, as exemplified with GIr4-001 as organic light-emitting diode devices. The OLED devices has a structure including: Substrate, anode, hole transmission layer, organic light-emitting layer, electron transmission layer and cathode.

In the device making of the invention, the substrate is glass, the anode material is indium tin oxide (ITO); the hole transmission layer is made of 4,4′-Cyclohexylidenebis [N,N-bis(4-methylphenyl)aniline] (TAPC), the electron transmission layer is made of 3,3′-(5′-(3-(pyridin-3-ylphenyl)phenyl)-[1,1′:3′,1″-triphenyl]-3,3″-diyl) bipyridine (TmPyPB) material, with a thickness of 60 nm and a vapor deposition rate of 0.05 nm/s; the cathode is made of LiF/Al, LiF with a thickness of 1 nm and a vapor deposition rate of 0.01 nm/s, Al with a thickness of 100 nm and a vapor deposition rate of 0.2 nm/s. The organic light-emitting layer is in a doped structure, the body is made of 1,3-bis(9H-carbazol-9-yl)benzene/mCP, the selected luminous material is GIr4-001. The light-emitting layer has a thickness of 40 nm, a vapor deposition rate of 0.05 nm/s, a GIr4-001 mass fraction of 8%.

The materials used in the invention have the following structures:

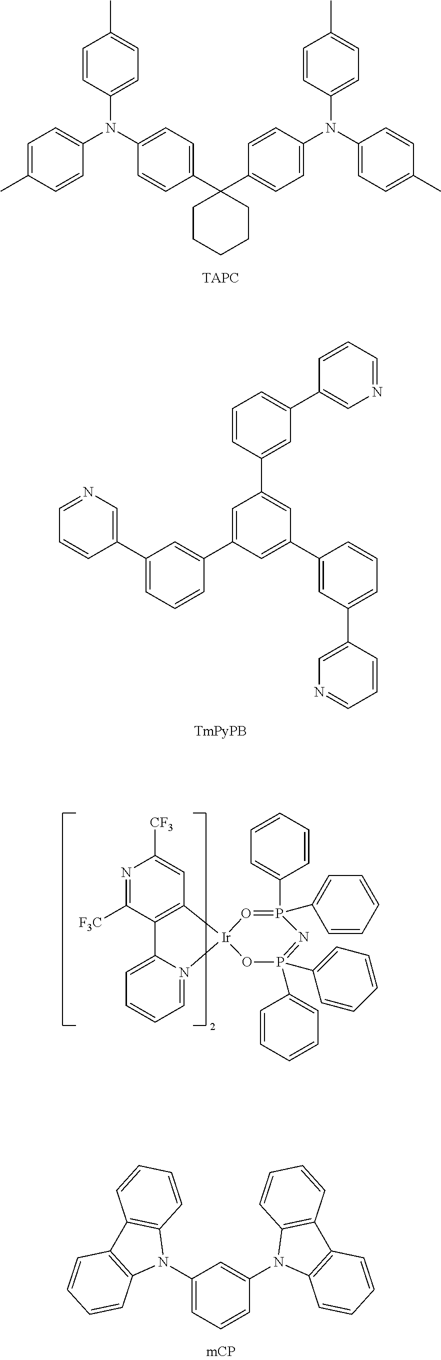

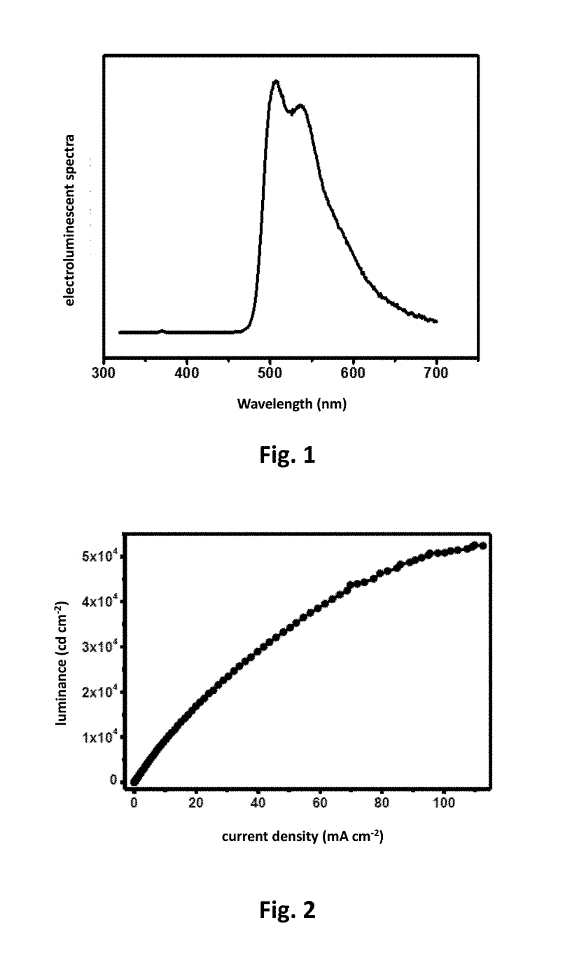

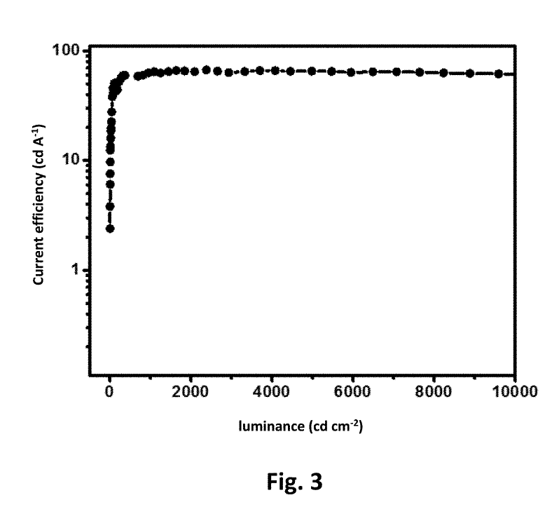

The invention selects a green emitting complex for preparing organic light-emitting diode devices. Please refer to FIG. 1, FIG. 2 and FIG. 3, FIG. 1 is the electroluminescence spectrum of the iridium complex used for organic light-emitting diode devices provided by the invention, FIGS. 2 and 3 are the photoelectric properties of the iridium complex used for organic light-emitting diode devices provided by the invention. As shown in FIGS. 2 and 3, the maximum power efficiency and current efficiency of the organic light-emitting diode devices are 43.34 lm/W and 101.96 cd/A respectively, with a maximum luminance of 52525 cd/m2 Through studies of photophysical properties, the phosphorescent iridium complexes containing azacycle have actual application value in the fields of display and lighting.

The phosphorescent material provided by the invention can act as luminescence center and applied in emitting layer of phosphorescent OLED, by design of ligand or complex structure, and by modification of chemical substituent of the ligand, the invention achieves the goal of regulating emitting color and efficiency.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. An iridium complex, comprising two primary ligands and a tetra(4-fluorophenyl)phosphorane as an auxiliary ligand, the primary ligands selected from one of 2-(4,6-bi trifluoromethyl)pyridine, 2-(4,6-bi trifluoromethyl)pyrimidine, 2-(4,6-bi trifluoromethyl)pyrazinyl and 2-(4,6-bi trifluoromethyl) triazine derivatives, wherein
the pyridine derivatives ligating with iridium by C atom are: 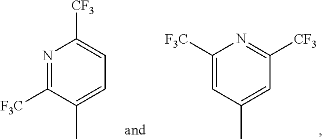
the pyridine derivatives have different positions of linking with the pyridine, pyrimidine, pyrazinyl and triazine derivatives in primary ligands, and the arbitrary positions of the pyridine, pyrimidine, pyrazinyl and triazine derivatives are substituted by halogen or alkyl, the number of substituent groups on the pyridine are 0-4, that on the pyrimidine and pyrazinyl are 0-3, that on the triazine are 0-2.

2. The iridium complex as described in claim 1, wherein the halogen is F, the alkyl group is any one of trifluoromethyl and methyl.

3. The iridium complex as described in claim 1, wherein the 4,6-bi trifluoromethyl in the primary ligands has different positions of linking with the pyridine, pyrimidine, pyrazinyl and triazine derivatives in different primary ligands, which are taken from 3-position and 4-position; the pyridine, pyrimidine, pyrazinyl and triazine derivatives are selected from

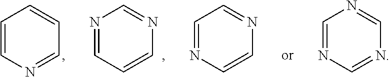

4. The iridium complex as described in claim 3, wherein the iridium complex has one of the following structures:

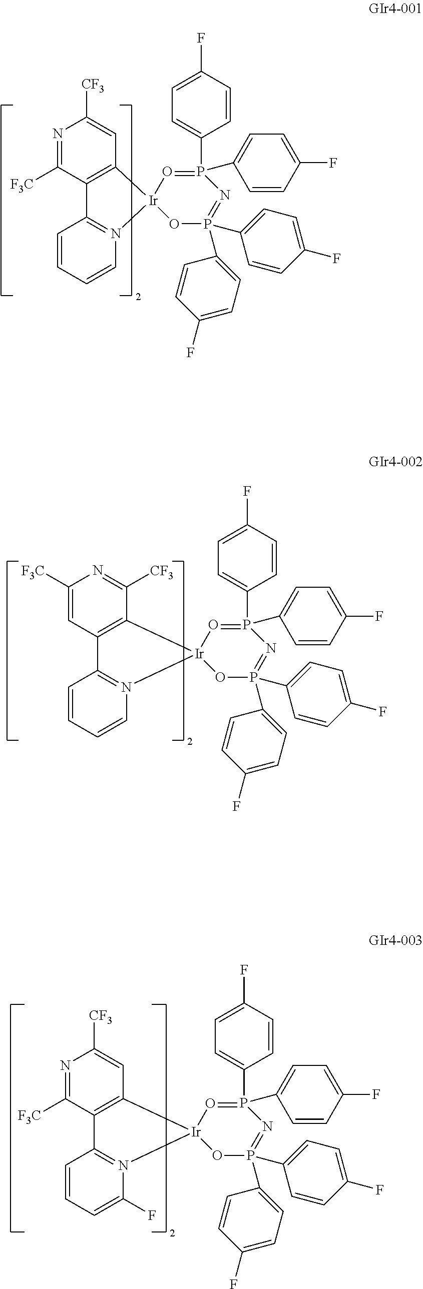

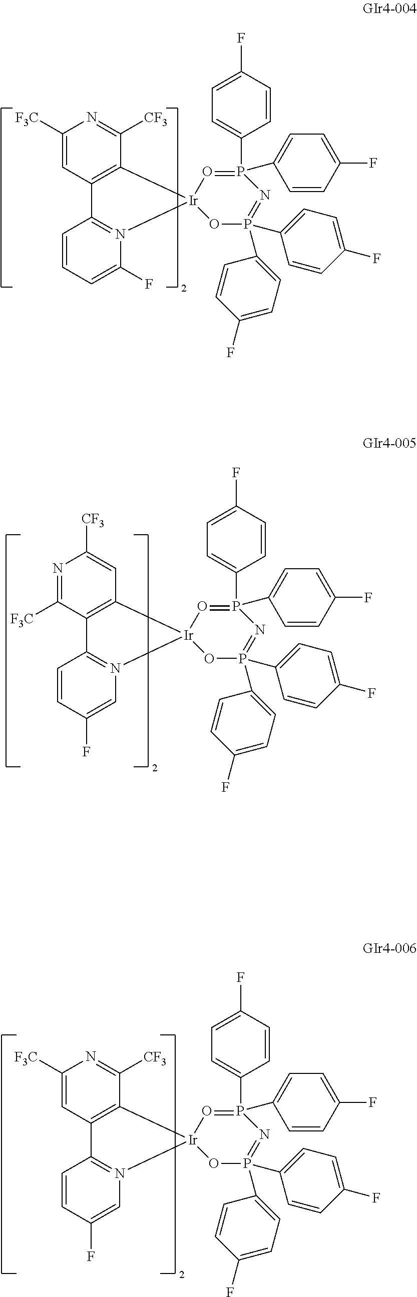

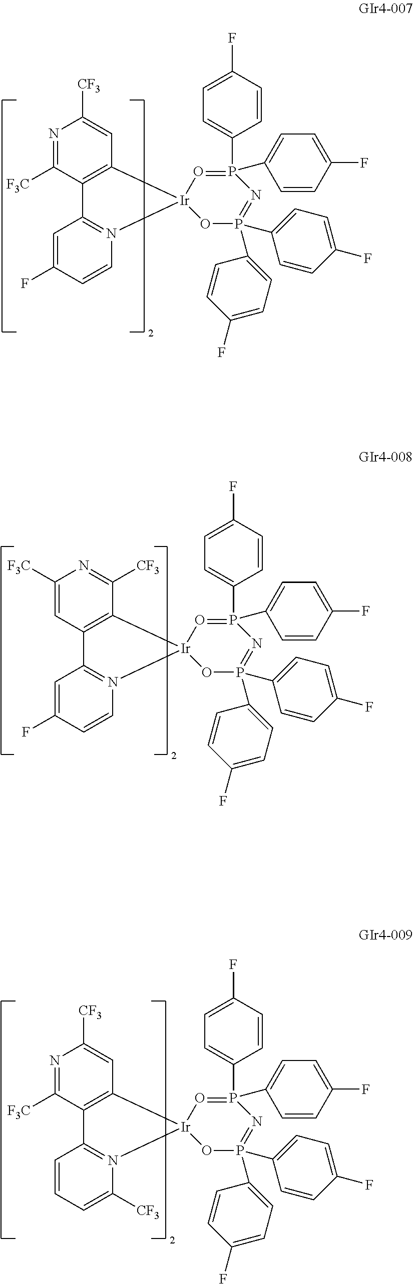

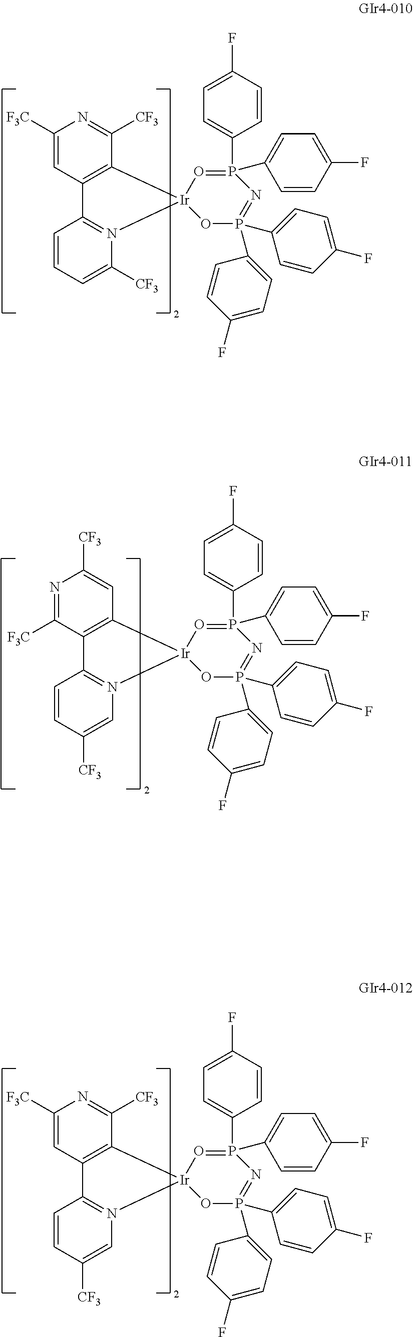

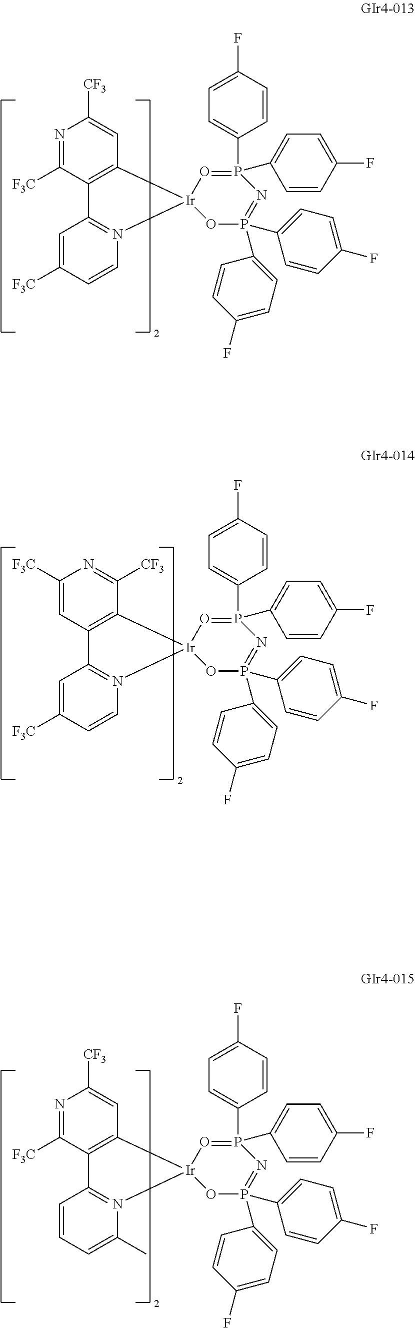

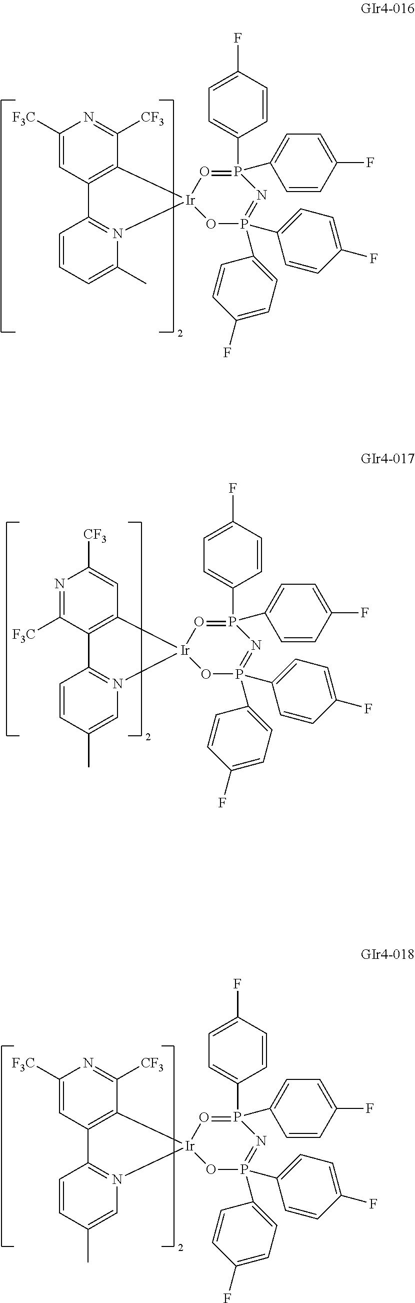

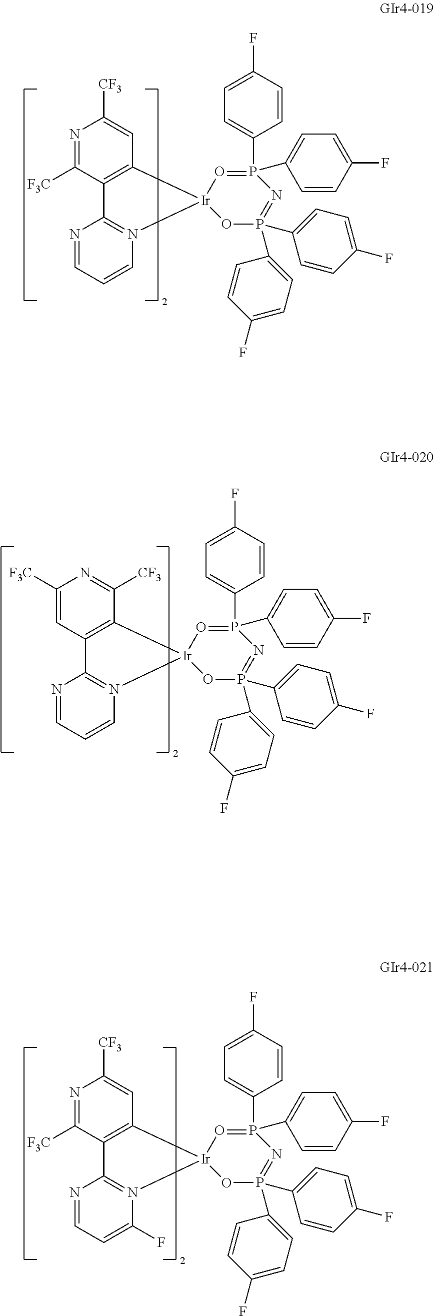

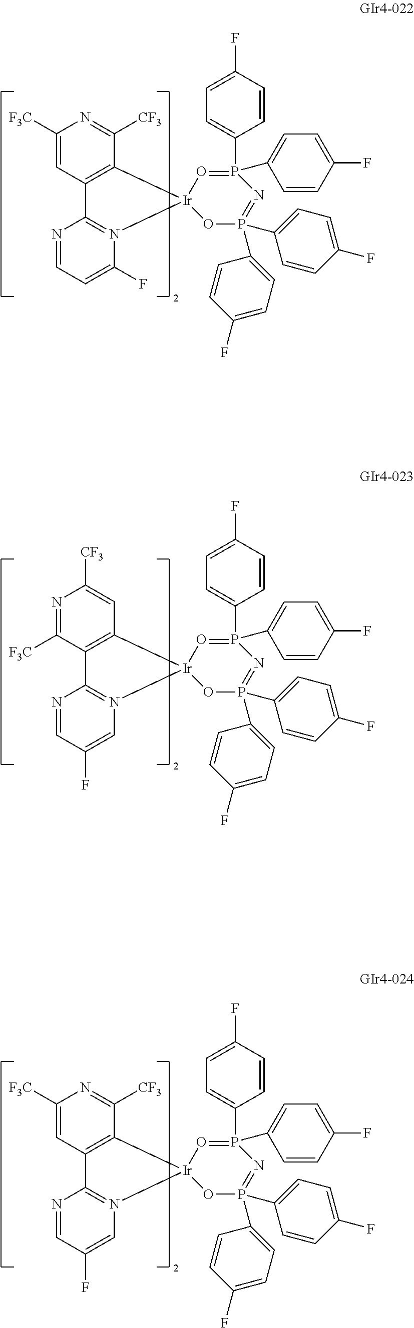

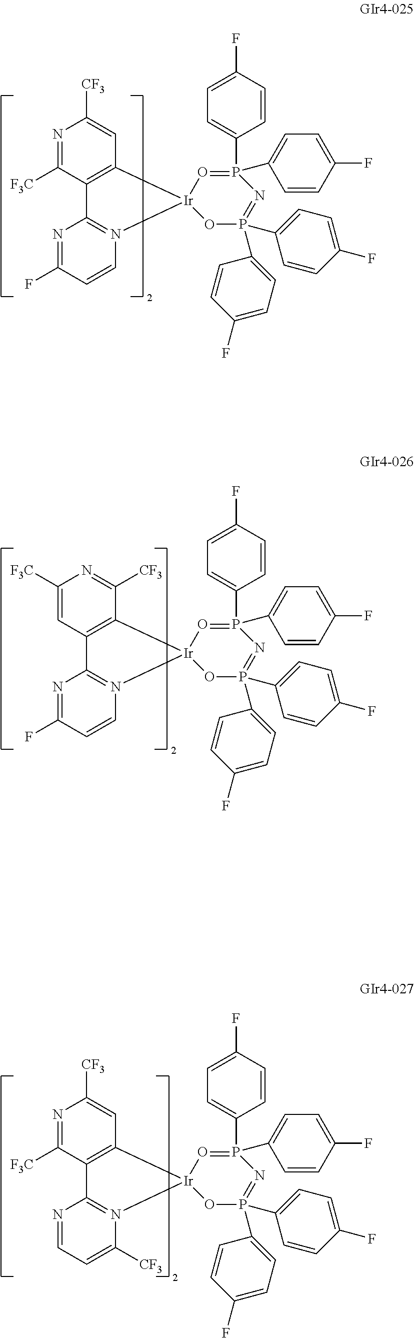

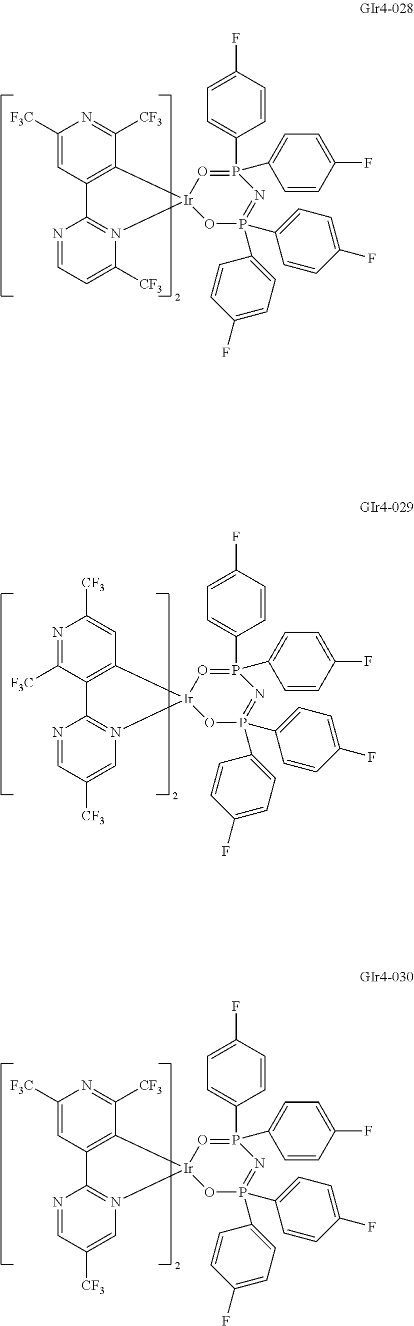

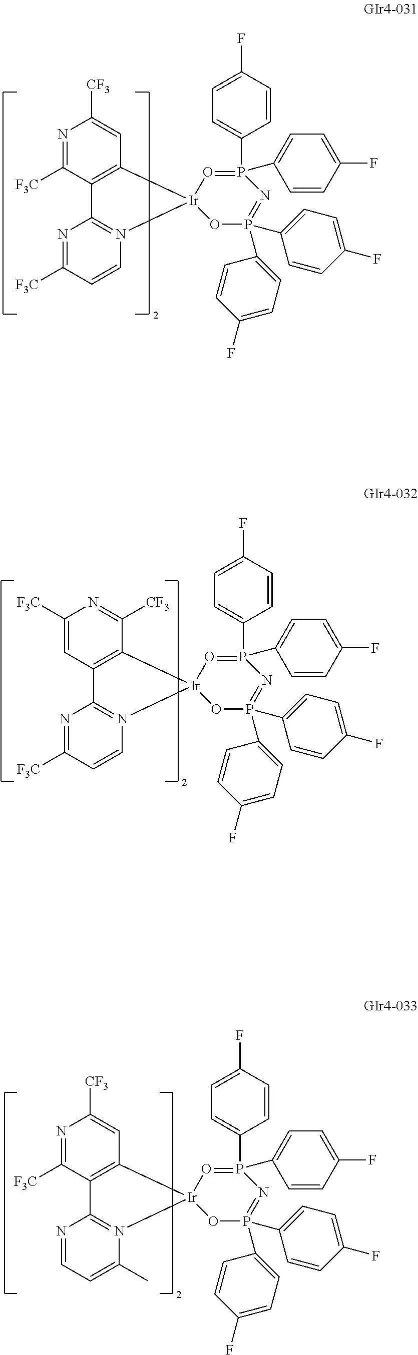

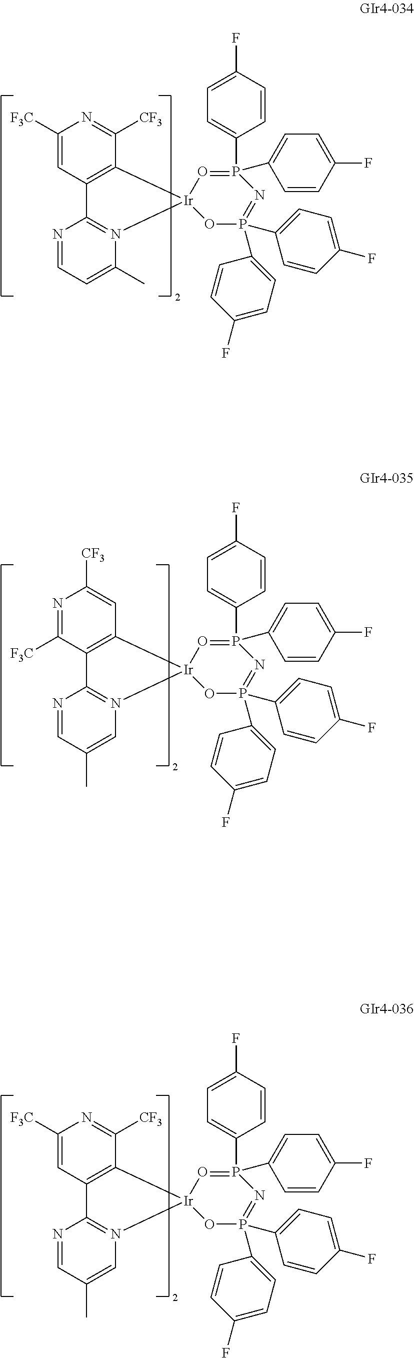

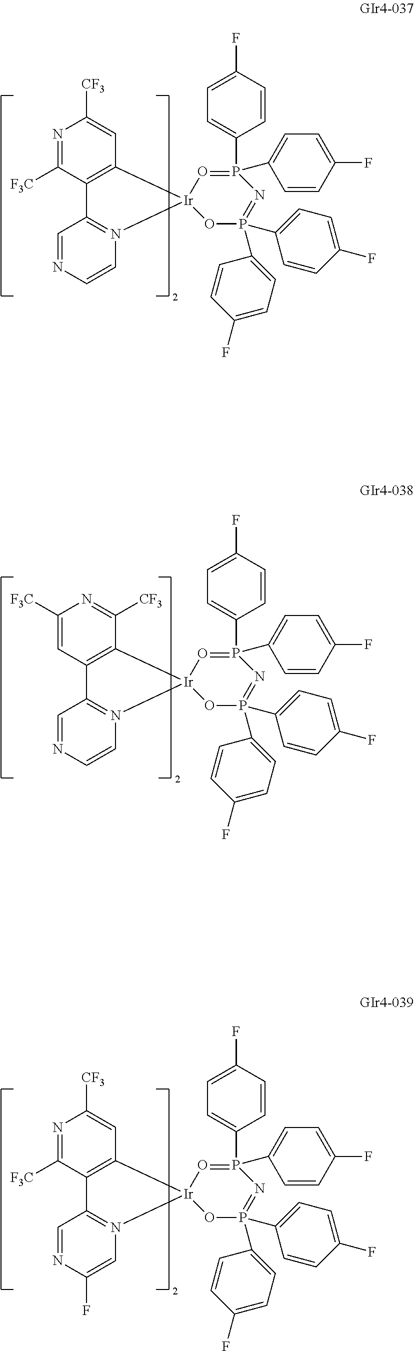

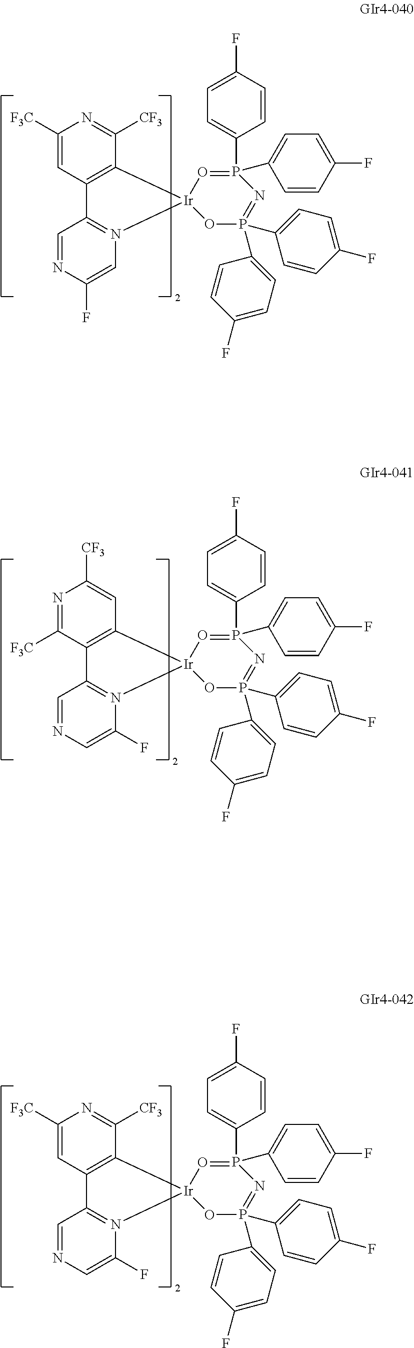

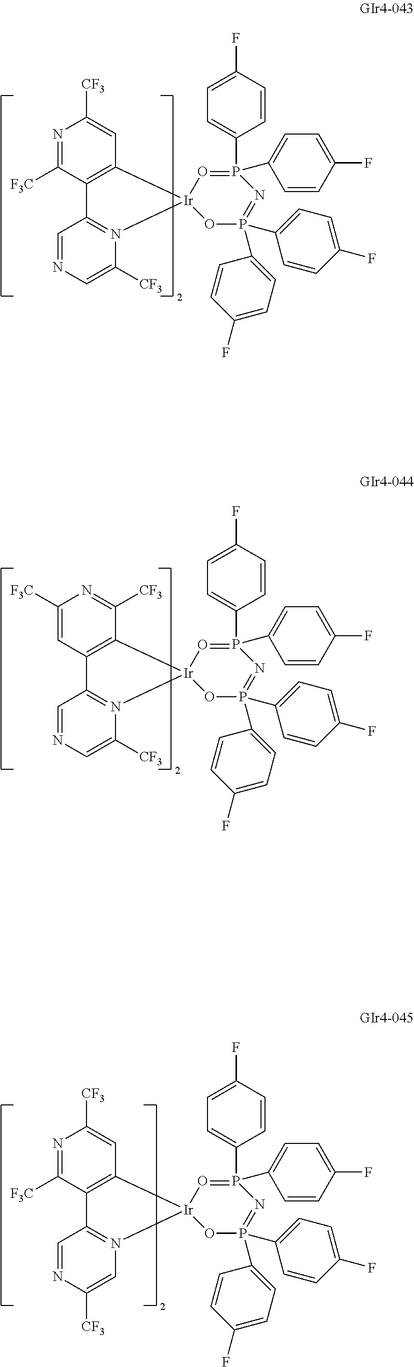

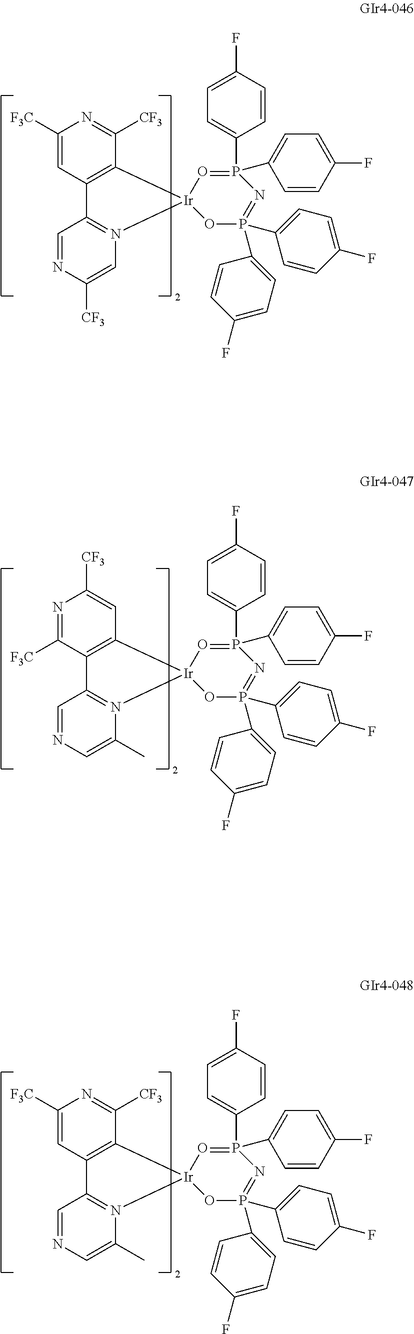

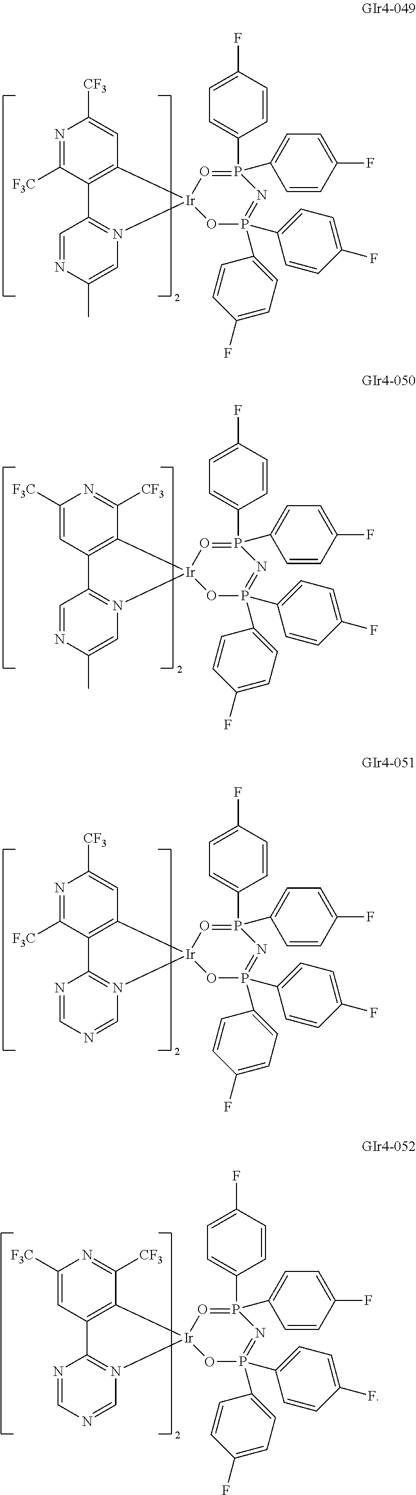

5. A manufacturing method of iridium complex including the steps of:
mixing iridium dimer bridging ligand which contain two primary ligands with tetra(4-fluorophenyl)phosphorane auxiliary ligand and sodium carbonate, wherein the primary ligands are any one of 2-(4,6-bi trifluoromethyl)pyridine, 2-(4,6-bi trifluoromethyl)pyrimidine, 2-(4,6-bi trifluoromethyl)pyrazinyl and 2-(4,6-bi trifluoromethyl) triazine derivatives;
adding the mixed liquor into 2-ethoxyethanol solution;
conducting heating reaction under 120-140° C. for a reaction time of 12-48 h, and cooling to room temperature;
eliminating the solvent through depressurization and distillation;
extracting and concentrate with dichloromethane, getting the crude product of the ligand through column chromatography isolation, and getting pure iridium complex through distillation.

6. The manufacturing method of iridium complex as described in claim 5, wherein the mole ratio of the iridium dimer bridging ligand, the tetra(4-fluorophenyl)phosphorane, and the sodium carbonate is 1:2:5.

7. An organic light-emitting device applying the iridium complex as described in claim 1, comprising a substrate, an anode, a hole transport layer, an organic light-emitting layer, an electron transport layer and a cathode; wherein the substrate is glass, the anode is indium tin oxide, the hole layer is made of TAPC material, the electron transport layer is made of TmPyPB material, the organic light-emitting layer comprises body material and luminous material, the body material is 1,3-bis(9H-carbazol-9-yl)benzene/mCP, the luminous material comprises the iridium complex.
